(19) United States
(12) Patent Application Publication
(10) Pub. No.: US 2010/0321217 A1
(43) Pub. Date: Dec. 23, 2010

(54) CONTENT ENCODING

(76) Inventor: VEERESH RUDRAPPA KORATAGERE, Tumkur, Karnataka (IN)

Correspondence Address: Koratagere Veeresh Rudrappa, Ambida Nilaya, #1100, 33rd Cross, Sit Ext, Tumkur, Karnataka, 572103, IN

(21) Appl. No.: 12/867,251

(22) PCT Filed: Sep. 30, 2009
(86) PCT No.: PCT/IN09/00536

§ 371 Date: Aug. 12, 2010

(30) Foreign Application Priority Data
Oct. 15, 2008 (IN) 2510/CHE/2008

(51) Int. Cl. H03M 7/30

(52) U.S. Cl. 341/87

(57) ABSTRACT

Embodiments of the invention include a method and system for data compression which includes receiving as input a data stream, the data stream comprising a sequence of symbols, identifying one or more repetitive sequence of symbols in the data stream, encoding each of the one or more repetitive sequence, replacing the one or more repetitive sequence of symbols that has been encoded with a single symbol representing the one or more repetitive sequence, repeating the steps until all repetitive sequences identified in the symbols of data stream are encoded, wherein the encoding is preformed by computing a binomial coefficient for each of the one or more repetitive sequences identified, forming a reduced sequence of symbols that were not encoded and statistically encoding the reduced sequence.

### PRIORITY DETAILS

This application claims priority of previously filed application number 2510/CHE/2008, titled “Content Encoding” filed on Oct. 15, 2008, 2511/CHE/2008, titled “Loseless Content Encoding” filed on Oct. 15, 2008 and 2512/CHE/2008 titled “Loseless Compression” filed on Oct. 15, 2008 at the Indian Patent Office, the contents of which are herein incorporated in entirety by reference.

### TECHNICAL FIELD

Embodiments of the invention generally relates to encoding/compression of content, and more particularly to using chunks within a content stream for developing an efficient encoding/compression technique.

### BACKGROUND

Various methods of compressing data have been developed over the past years. Because of the increased use of computer systems, requirements for storage of data have consistently increased. Consequently, it has been desirable to compress data for the purpose of speeding both transmission and storage of the data. Of the various techniques know for data compression, one of the techniques that is widely used is run length encoding.

Run-length encoding (RLE) is a very simple form of data compression in which runs of data (that is, sequences in which the same data value occurs in many consecutive data elements) are stored as a single data value and count, rather than as the original run. This is most useful on data that contains many such runs, for example, relatively simple graphic images such as icons, line drawings, and animations. This technique is not recommended for use with files that don't have many runs as it could potentially double the file size.

Run length encoding includes a series of repetitive data symbols that are compressed into a shorter code which indicates the length of a code and the data being repeated. A large number of different ways of run length encoding have been developed. Without a way to provide an improved method and system of compressing data, the promise of this technology may never be fully achieved.

### SUMMARY

Embodiments of the invention relates generally to a method and system for data compression where when an input data stream which contains a sequence of symbols is received, a chunk within the data stream which represent a repetitive symbol within the sequence is identified, the first boundary position and the end boundary position for the chunk is identified and the chunk is encoded using a binomial coefficient, which is configured to form a first part of the result and the remaining symbols forming the second part of the sequence, which also contain the first character of the chunk. The second part of the result can then be further encoded using any standard compression/encoding algorithms.

In one embodiment, the method is implemented by one or more computer programs. The computer programs may be stored on a computer-readable medium. The computer-readable medium may be a tangible medium, such as a recordable data storage medium, or an intangible medium, such as a modulated carrier signal.

Still other advantages, aspects, and embodiments of the disclosure will become apparent by reading the detailed description that follows, and by referring to the accompanying drawings.

### BRIEF DESCRIPTION OF THE DRAWINGS

The drawings referenced herein form a part of the specification. Features shown in the drawing are meant as illustrative of only some embodiments of the invention, and not of all embodiments of the invention, unless otherwise explicitly indicated, and implications to the contrary are otherwise not to be made.

FIG. 1 is an exemplary illustration of a block diagram illustrating the manner in which the compression/decompression techniques of the disclosure may be employed;

FIG. 2 is an exemplary embodiment of a block diagram further defining the manner in which the disclosure may be employed;

FIG. 3 is an exemplary embodiment of a method illustrating the manner in which the disclosure may be employed; and

FIG. 4 is an exemplary embodiment of a system diagram of a computer system on which at least one embodiment of the disclosure may be implemented.

### DETAILED DESCRIPTION

In the following detailed description of exemplary embodiments of the invention, reference is made to the accompanying drawings that form a part hereof, and in which is shown by way of illustration specific exemplary embodiments in which the invention may be practiced. These embodiments are described in sufficient detail to enable those skilled in the art to practice the invention. Other embodiments may be utilized, and logical, mechanical, and other changes may be made without departing from the spirit or scope of the present invention. The following detailed description is, therefore, not to be taken in a limiting sense, and the scope of the present invention is defined only by the appended claims.

Embodiments of the invention related to a method for data compression, wherein the method includes receiving as input a data stream, the data stream comprising a sequence of symbols; identifying one or more repetitive sequence of symbols in the data stream; encoding the one or more repetitive sequence forming a first part containing an encoded value and replacing the repetitive sequence of symbols with a single symbol and a second part in which all symbols in the data stream of symbols that were not encoded forming a reduced sequence; and repeating the method steps disclosed above until all repetitive sequences identified in the symbols of data stream are encoded.

In a further embodiment of the invention, encoding the one or more repetitive sequences includes computing a binomial value for each of the one or more repetitive sequence, and summing the binomial value for the each of the one or more repetitive sequence of symbols.

In a further embodiment of the invention, identifying the one or more repetitive sequences comprises for each of the repetitive sequence of symbols in the data stream includes determining a first boundary position defining a start of the sequence of symbols and a second boundary position defining an end of the sequence of symbols for the one or more repetitive sequences within the data stream, wherein the first and second boundary position define an identical symbol. The method then includes encoding the first boundary position and the second boundary position for each of the one or more repetitive sequences of the data stream, and computing binomial values for the first boundary position and the second boundary position for each of the one or more repetitive sequences of the data stream; summing the binomial values computed for each of the one or more repetitive sequences of the data stream; storing the sum of the binomial values; and replacing the one or more repetitive sequence of symbols with a single symbol in the reduced sequence. Yet a further embodiment of the includes for each of the repetitive sequence of symbols in the sequence of data stream being replaced by a single symbol thereby forming a reduced sequence, and the reduced sequence may be encoded using a statistical encoding technique. Further, encoding the position of the start byte or symbol and the end byte or symbol of each one of the repetitive sequences of the data stream is performed using a binomial, and the encoded positions are stored as binomial coefficients.

Yet a further embodiment of the invention includes a system configured to perform the method as disclosed above, especially when the method is operational on the system, and such a system for example may include an electronic device such as a computer system, laptop, etc and may also include portable electronic device such as PDA's, mobile phones, tablet PC's etc.

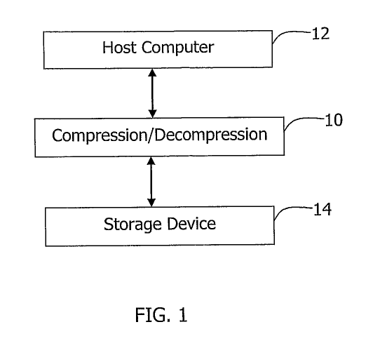

FIG. 1 is an exemplary embodiment of a block diagram illustrating the manner in which the compression/decompression system 10 of the disclosure may be employed in the transfer of data from a host computer 12 to a storage device 14 and vice versa. Although FIG. 1 illustrates one implementation of the disclosure, and it should be apparent to one skilled in the art that the disclosure can also be employed to compress and/or decompress data in any data translation or transmission system desired. For example, the disclosure may be used to compress and/or decompress data in a data transmission system for a facsimile system between two remote locations. Additionally, the disclosure may be used for compressing and/or decompressing data during transmission of data within a computer system.

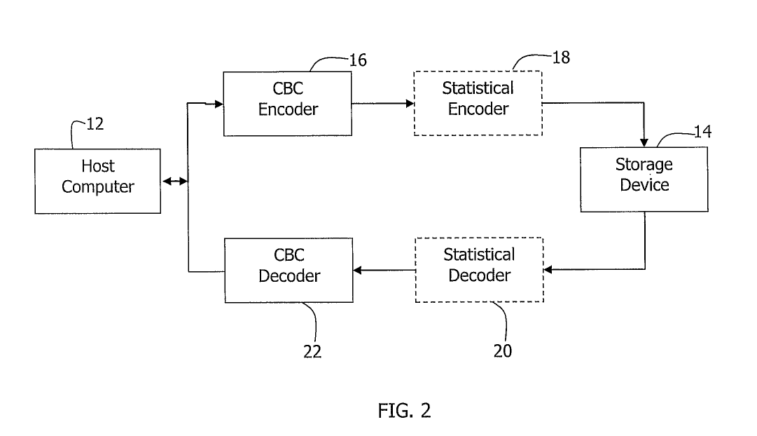

FIG. 2 is an exemplary embodiment of a block diagram illustrating the manner of compression and decompression used in an embodiment of the invention. Compression is accomplished, in accordance with the disclosure, by encoding in a chunk based encoder (CBE) 16. The encoded data produced at the output of CBE 16 is then statistically encoded in statistical encoder 18. The statistical encoder 18 is illustrated in dotted line, indicating that after performing chunk based encoding, it is not necessary to perform statistical encoding on the data. The decoding process of the disclosure is accomplished by first statistically decoding the statistically encoded data in statistical decoder 20. The statistically decoded data from statistical decoder 20 is then decoded in chunk based decoder 22. CBE 16 comprises the first stage in the compression process. CBE 16 scans the data for characters which repeat themselves in the data stream from host computer 12 and encodes them using a technique called chunk based encoding.

Data stream from the host computer 12 is encoded using chunk based encoding technique at the CBE 16. CBE 16 first receives the input data from host computer 12. The input data received at the CBE 16 contains a sequence of symbols. CBE 16 now scans the input data received to determine patterns that are repetitive. For example consider the input data received by the CBE 16 to be of format “ABBBBBBBAAAAAACCCCDEFAAAAAAGGGHJ”. The exemplary input data above shows 32 symbols and also illustrated illustrative patterns that are marked as italics. The first character of the input data is the symbol “A” This is considered to be position 0. The next character is a repetitive sequence “B”, starting at position 1 and ending at position 7. According to an embodiment of the invention, position 1 is considered as the starting boundary value of the sequence “B” and position 7 is considered as the ending boundary value of the sequence “B”. Next in the series of the input data is the sequence “A”, starting at position 8 and ending at position 13. Next in the series is the sequence “C” starting at position 14 and ending at position 17. Next in the sequence is the symbol D at position 18, E at position 19 and F at position 20. Next again is the repetitive sequence “A” starting at position 21 and ending at position 26, after which is the sequence “G” starting at position 27 and ending at position 29. Then the symbol “H” at position 30, and symbol “J” at position 31. The entire sequence of input data starting from “A” and ending at “J”, with “A” at 0 and ending “J” at 31, forms 32 bits. Each of the repetitive sequence in the input data stream is referred to as a chunk.

For the input data “ABBBBBBBAAAAAACCCCDEFAAAAAAGGGHJ”, each repetitive sequence is noted. Let “1” denote the length of the sequence that needs to be encoded. For example, in the above sequence the symbol “B” is repetitive from starting position 1 and ending position 7. These positions are considered to be boundary values for each of the symbols in the sequence. For each of the repetitive sequence, the boundary values are noted and binomial coefficient is computed. For each of the chunks, the start position and the end position are noted. Every chunk therefore is a representation of two values (Pₛₙ, Pₑₙ), wherein Pₛ denoted the start of the sequence and Pₑ denotes the end of the sequence, and the subscript “n” denotes the n^{th} chunk.

CBE 16 now computes the binomial value for the chunk using the start value and the end value being defined as boundary values, which are computed using the formula

$$( \begin{matrix}{P}_{sn} \\ 2 ( n - 1 ) + 1\end{matrix} ) and ( \begin{matrix}{P}_{en} \\ 2 n\end{matrix} )$$

Once the binomial values are computed for each of the chunks in the sequence of input data, the binomial values that are computed are summed thereby forming a single large number E(c)

$$E ( c ) = {\sum }_{n = 1}^{end of sequence} ( \begin{matrix}Psn \\ 2 ( n - 1 ) + 1\end{matrix} ) + ( \begin{matrix}Pen \\ 2 n\end{matrix} )$$

Now the input data “ABBBBBBAAAAAACCCCDEFAAAAAAGGGHJ” will be easily replaced as follows E(c)+ABACDEFAGHJ==E(c)+E(R), wherein after computing the binomial value, the first character of each of the sequence of the chunk is retained along with other sequences forming a second part, which represents a sequence. E(c) gives the encoded value for the run length, of chunks. The second part “ABACDEFAGHJ” now is a reduced sequence (R), which can be further encoded using any statistical encoding techniques that are available in the art, for example, Huffman coding, arithmetic coding and the likes.

E(c) provides the encoded value for the run lengths of each of the chunks in the input data. The second part of the sequence R can be encoded using for example any of the known statistical encoding techniques as E(R). E(c), E(R), n and l are written to the file, in the form for example as [length of sequence, number of chunks in the sequence, E(C)], where for the sequence discussed above, the length of the sequence is 20 and the number of chunks is 5, which means the number of boundary position is 10. Chunk based coding leads to better compression than that provided by run length coding or any other forms of available compression.

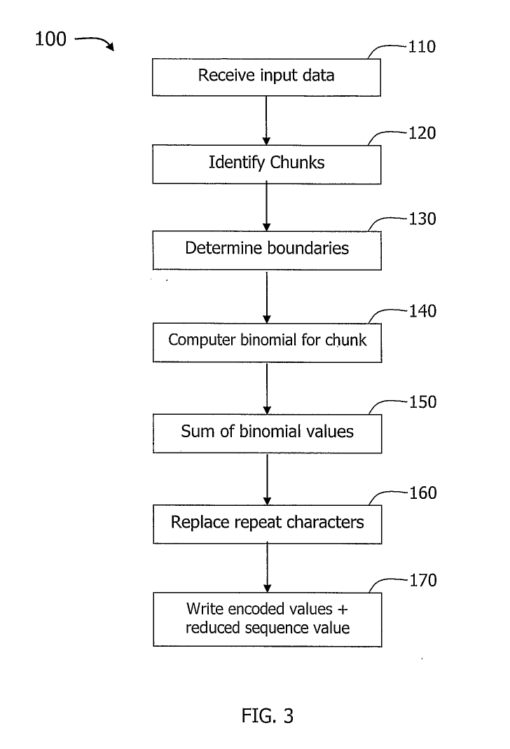

FIG. 3 illustrates an exemplary embodiment of a method 100 which illustrates a manner in which the disclosure may be implemented. At Step 110 input data is received, as mentioned above, the input data is received by the CBE 16, the input data contains a sequence of symbols. Once the input data is received, the input data is scanned to determine repetitive sequences which form so called chunks, as illustrated previously, in Step 120. Once the chunks are identified in the input data, in Step 130, for each of the chunks the starting boundary position and the ending boundary positions are encoded by means of a binomial value in Step 140. A binomial value for each of the chunks in the input data received is computed. In step 150, each of the binomial values computed is summed to form a large integer. Each of the chunks is replaced by a single character and the individual symbols are maintained in that order forming a second part which is a reduced sequence in Step 160. This has been illustrated previously. Notably, the reduced sequence can be further compressed using any of the standard techniques for example using statistical encoding techniques. The computed binomial value (summed value for all the chunks), the encoded value of the reduced sequence, the length of the sequence and the number of chunks in the sequence are then written to a file in Step 170. This chunk based encoding offers better compression ratio than techniques currently available in prior art.

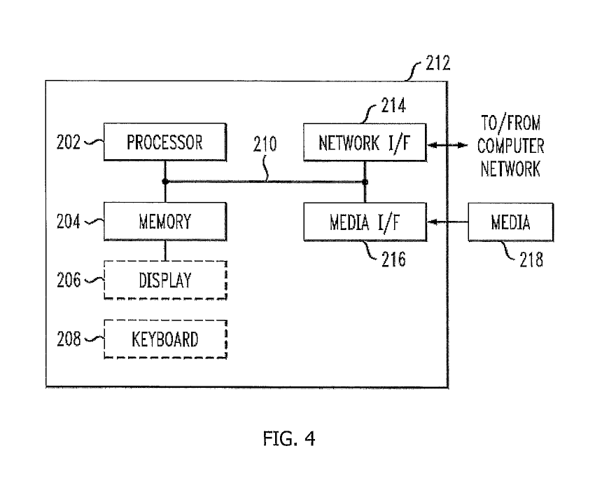

At present, it is believed that the implementation will make substantial use of software running on a general-purpose computer or workstation. With reference to FIG. 4, such an implementation might employ, for example, a processor 202, a memory 204, and an input and/or output interface formed, for example, by a display 206 and a keyboard 208. The term “processor” as used herein is intended to include any processing device, such as, for example, one that includes a CPU (central processing unit) and/or other forms of processing circuitry. Further, the term “processor” may refer to more than one individual processor. In one embodiment, the processor can include the CBE and the statistical encoder. The term “memory” is intended to include memory associated with a processor or CPU, such as, for example, RAM (random access memory), ROM (read only memory), a fixed memory device (for example, hard drive), a removable memory device (for example, diskette), a flash memory and the like. In addition, the phrase “input and/or output interface” as used herein, is intended to include, for example, one or more mechanisms for inputting data to the processing unit (for example, mouse), and one or more mechanisms for providing results associated with the processing unit (for example, printer). The processor 202, memory 204, and input and/or output interface such as display 206 and keyboard 208 can be interconnected, for example, via bus 210 as part of a data processing unit 212. Suitable interconnections, for example via bus 210, can also be provided to a network interface 214, such as a network card, which can be provided to interface with a computer network, and to a media interface 216, such as a diskette or CD-ROM drive, which can be provided to interface with media 218.

Accordingly, computer software including instructions or code for performing the methodologies of the invention, as described herein, may be stored in one or more of the associated memory devices (for example, ROM, fixed or removable memory) and, when ready to be utilized, loaded in part or in whole (for example, into RAM) and executed by a CPU. Such software could include, but is not limited to, firmware, resident software, microcode, and the like.

Furthermore, the disclosure can take the form of a computer program product accessible from a computer-usable or computer-readable medium (for example, media 218) providing program code for use by or in connection with a computer or any instruction execution system. For the purposes of this description, a computer usable or computer readable medium can be any apparatus for use by or in connection with the instruction execution system, apparatus, or device.

The medium can be an electronic, magnetic, optical, electromagnetic, infrared, or semiconductor system (or apparatus or device) or a propagation medium. Examples of a computer-readable medium include a semiconductor or solid-state memory (for example, memory 204), magnetic tape, a removable computer diskette (for example, media 218), a random access memory (RAM), a read-only memory (ROM), a rigid magnetic disk and an optical disk. Current examples of optical disks include compact disk-read only memory (CD-ROM), compact disk-read and/or write (CD-R/W) and DVD.

In one embodiment, the encoder 16 constitutes the means for performing the method as described previously with respect to FIG. 3. Each of the method steps discussed previously can be performed in the means for encoding 16, thereby compressing/encoding the input data stream.

A data processing system suitable for storing and/or executing program code will include at least one processor 202 coupled directly or indirectly to memory elements 204 through a system bus 210. The memory elements can include local memory employed during actual execution of the program code, bulk storage, and cache memories which provide temporary storage of at least some program code in order to reduce the number of times code must be retrieved from bulk storage during execution.

Input and/or output or I/O devices (including but not limited to keyboards 208, displays 206, pointing devices, and the like) can be coupled to the system either directly (such as via bus 210) or through intervening I/O controllers (omitted for clarity).

Network adapters such as network interface 214 may also be coupled to the system to enable the data processing system to become coupled to other data processing systems or remote printers or storage devices through intervening private or public networks. Modems, cable modem and Ethernet cards are just a few of the currently available types of network adapters.

In any case, it should be understood that the components illustrated herein may be implemented in various forms of hardware, software, or combinations thereof, for example, application specific integrated circuit(s) (ASICs), functional circuitry, one or more appropriately programmed general purpose digital computers with associated memory, and the like. Given the teachings of the invention provided herein, one of ordinary skill in the related art will be able to contemplate other implementations of the components of the disclosure.

Although illustrative embodiments of the invention have been described herein with reference to the accompanying drawings, it is to be understood that the invention is not limited to those precise embodiments, and that various other changes and modifications may be made by one skilled in the art without departing from the scope or spirit of the embodiments of the invention.

1. A method for data compression, the method comprising
receiving as input a data stream, the data stream comprising a sequence of symbols;
identifying one or more repetitive sequence of symbols in the data stream;
encoding each of the one or more repetitive sequences; and
replacing the one or more repetitive sequence of symbols that has been encoded with a single symbol representing the one or more repetitive sequence.

2. The method as claimed in claim 1, wherein the step of identifying the one or more repetitive sequences comprises of each of the repetitive sequence of symbols in the data stream
determining a first boundary position defining a start of the sequence of symbols and a second boundary position defining an end of the sequence of symbols for the one or more repetitive sequences within the data stream, wherein the first boundary position and second boundary position define an identical symbol.

3. The method as claimed in claim 2, further comprising encoding the first boundary position and the second boundary position for each of the one or more repetitive sequences of the data stream.

4. The method as claimed in claim 1, further comprising
computing binomial values for the first boundary position and the second boundary position for each of the one or more repetitive sequences of the data stream;
summing the binomial values computed for each of the one or more repetitive sequences of the data stream; and
storing the sum of the binomial values representing the repetitive sequence of symbols.

5. The method as claimed in claim 1, wherein each of the symbols in the data stream not encoded and each of the symbols replacing the repetitive sequence of symbols in the data stream forming a reduced sequence.

6. The method as claimed in claim 4, wherein an encoded file comprises the length of the sequence of data stream, the number of repetitive sequences in the data stream, the summed binomial values of each of the repetitive sequences.

7. The method as claimed in claim 5, wherein the reduced sequence may be encoded using a statistical encoding technique.

8. A system comprising means for encoding/compressing data wherein the means for encoding/compressing data capable of performing at least one or more of the steps as claimed in any of the preceding claims 1 to 7.

9. A system configured to perform the method as claimed in any of the preceding claims 1 to 8.
